(19) United States
(12) Patent Application Publication
(10) Pub. No.: US 2005/0170555 A1
(43) Pub. Date: Aug. 4, 2005

(54) Method of manufacturing a semiconductor device including electrodes on main and reverse sides of a semiconductor chip

(75) Inventors: Naohiko Hirano, Okazaki-city (JP); Shoji Miura, Nukata-gun (JP); Akihiro Niimi, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/045,625

(22) Filed: Jan. 25, 2005

(30) Foreign Application Priority Data
Jan. 30, 2004 (JP) 2004-022999
Oct. 4, 2004 (JP) 2004-291396

(51) Int. Cl. H01L 21/44; H01L 21/4763

(52) U.S. Cl. 438/106; 438/113; 438/133

(57) ABSTRACT

A method for manufacturing a semiconductor chip includes preparing a semiconductor wafer to be oriented so that a main side and reverse side of the semiconductor wafer is oriented similar to a main side and reverse side of the semiconductor chip intended to be cut from the semiconductor wafer. An electrode is formed on a reverse side of the semiconductor wafer. Another electrode is formed on the main side of the semiconductor wafer while the reverse side of the wafer is fixed to a supporting substrate. The semiconductor wafer is cut later to form the semiconductor chip.

### CROSS REFERENCE TO RELATED APPLICATIONS

This application is based upon, claims the benefit of priority of, and incorporates by reference the contents of, Japanese Patent Application No. 2004-20073 filed on Jan. 28, 2004 and Japanese Patent Application No. 2004-291396 filed on Oct. 4, 2004

### FIELD OF THE INVENTION

The present invention relates generally to a method of manufacturing a semiconductor chip for a semiconductor device, and, more particularly, to such a chip having electrodes on main and reverse sides, and metal bodies as electrodes and radiators.

### BACKGROUND OF THE INVENTION

A conventional semiconductor chip includes an electrode formed on a main side and reverse side of the chip. The semiconductor chip may be a power element such as, for example, an IGBT (Insulated Gate Bipolar Transistor).

The semiconductor chip of the IGBT or the like is then bound by a metal body such as a heatsink or the like, and almost entirely molded with resin to thereby encapsulate the semiconductor chip while the electrodes on both sides are electrically and thermally connected to the metal body. Such a chip is disclosed in patent documents JP-A-2002-110893 and JP-A-2003-110064.

A conventional method of manufacturing a semiconductor chip having electrodes on both sides as described above is shown in FIG. 3A and FIG. 3B.

The semiconductor chip is manufactured on a semiconductor wafer by conventional semiconductor processing techniques so that each chip is manufactured as a unit and then cut out from the wafer to form the individual chip by using a dicing cutter or the like.

As shown in FIG. 3A, an element (not shown) and an Al—Si layer are formed on the surface of a semiconductor wafer 100 made of a silicon or the like by thermal diffusion, ion implantation or the like (element formation process/Al—Si layer formation process).

A protection film 14 made of polyimide is formed on the semiconductor wafer 100. An opening 14a is formed in the protection film 14 (protection film formation process). Then, a plating layer 12 for providing a surface electrode is formed on the Al—Si layer exposed in the opening 14a by plating (plating layer formation process).

The plating layer 12 is usually formed by electroless Ni/Au plating as a composite plating film with an underlying Ni—P plating layer and an Au plating layer. In this manner, a plating layer 12 forms an electrode on the main side of the semiconductor chip. The Ni—P contains a ratio of P (phosphorus) to Ni of approximately 5 to 15 weight percent.

After this process, an Al layer, a Ti layer, and an Au layer as a reverse side electrode are formed in this order on the reverse side of the semiconductor wafer 100 by a sputtering technique or the like.

The semiconductor wafer is then divided into each semiconductor chip by a dicing cutter.

The inventors have determined that extreme warpage may occur during the semiconductor chip formation process as shown in FIG. 3B. In this case, when the semiconductor wafer has a thickness t of 250 μm or less with electrodes 12, 13 formed on both surfaces, the difference of heat expansion coefficient between the electrodes 12, 13, and the material for composing the semiconductor wafer 100 such as a silicon or the like causes warpage.

The warpage of this kind may cause a breakage of the semiconductor wafer. The warpage also causes a problem in later processes, such as a difficulty in testing the wafer characteristics, or in cutting the wafer.

In view of the above-described problem, it is an object to provide a semiconductor wafer manufacturing process in which warpage of the wafer is minimized when manufacturing a semiconductor chip used in an almost entirely resin molded semiconductor device having metal bodies as electrodes and radiators connected to the electrodes on both sides of the chip.

### SUMMARY OF THE INVENTION

In a method for manufacturing a semiconductor chip having an electrode formed on a main side and a reverse side of the chip, a metal body as an electrode and a radiator attached on each of the main side and the reverse side of the chip, and a resin mold covering almost an entire body of the chip, according to a first aspect, a semiconductor wafer from which a semiconductor chip will be cut out in the same orientation with respect to the main side and the reverse side is prepared, an electrode is formed on the reverse side of the semiconductor wafer, an electrode is formed on the main side of the semiconductor wafer while the reverse side of the wafer is fixed to a supporting substrate, and the semiconductor wafer is cut out (diced) to form the semiconductor chip.

In this method, because the semiconductor wafer is fixed on the supporting substrate before forming the electrodes on both sides of the semiconductor wafer, warpage of the semiconductor wafer can be minimized.

According to a second aspect, in the method for manufacturing a semiconductor chip according to the above first aspect, a supporting substrate having a greater rigidity than that of the semiconductor wafer is used.

According to a third aspect, in the method for manufacturing a semiconductor chip according to any of the above first and second aspects, the supporting substrate is comprised of quartz.

According to a fourth aspect, in the method for manufacturing a semiconductor chip according to any of the above first through third aspects, the supporting substrate has a thickness of 0.4 mm or more.

According to a fifth aspect, in the method for manufacturing a semiconductor chip according to any of the above first through fourth aspects, the semiconductor wafer has a thickness of 250 μm or less. In this manner, the warpage of the semiconductor wafer is appropriately prevented.

According to a sixth aspect, in the method for manufacturing a semiconductor chip according to any of the above first through fifth aspects, the electrode on the main side is comprised of an Ni—P layer and an Au layer stacked on an aluminum layer and the main side of the semiconductor chip is an active region side.

According to a seventh aspect, in the method for manufacturing a semiconductor chip according to the above sixth aspect, the Ni—P layer and the Au layer are formed by wet electroless deposition.

According to an eighth aspect, in the method for manufacturing a semiconductor chip according to the above sixth aspect, the Ni—P layer of the electrode has a P density of 5 to 15% by weight and a thickness of 3 μm or more.

When the density of P in the Ni—P layer is too thick, the Ni—P layer in the electrode on the main side of the semiconductor chip and the Sn in the solder react to form a P thickened layer in the proximity of the interface of the underlying Al layer during the soldering process. This will result in an exfoliation of the Ni—P layer and the Al layer with ease.

Further, the P in the Ni—P layer acts as a core of film formation in the wet electroless deposition. When the density of P is too thin, formation of Ni—P layer is difficult. It will also make the Ni—P layer hard because of the richness of Ni. The hard film layer is not preferable because it is easy to warp.

Furthermore, when the Ni—P layer is too thin, the above-mentioned P thickened layer will be formed in the proximity of the interface of the underlying Al layer, thereby resulting in an easy exfoliation of the Ni—P layer from the Al layer.

Therefore, the Ni—P layer of the electrode preferably has a P density of 5 to 15% by weight and a thickness of 3 μm or more.

According to a ninth aspect, in the method for manufacturing a semiconductor chip according to the above sixth aspect, the Au layer in the electrode preferably has a thickness of 0.02 to 0.2 μm.

The Au layer in the electrode on the main side of the semiconductor chip is formed to prevent oxidization of the underlying layer. The thickness of the Au layer has to be 0.02 μm or more to be an anti-oxidization film.

The Au layer of thickness of 0.2 μm or more will form an Al—Au—Ni alloy in the wire bonding process of the electrode formed on the main side of the semiconductor chip. This alloy is easy to corrode, and thus the thickness of the Au layer has to be 0.2 μm or less.

Therefore, the Au layer in the electrode on the main side of the semiconductor chip preferably has a thickness of 0.02 to 0.2 μm.

According to a tenth aspect in the method for manufacturing a semiconductor chip according to the above sixth aspect, the Ni—P layer in the electrode has a P density of 5 to 15% in weight and a thickness of more than 3 μm, the Au layer in the electrode has a thickness of 0.02 to 0.2 μm, and the Ni—P layer and the Au layer are formed by wet electroless deposition.

In this manner, the effect of the seventh through ninth aspects will be combined.

According to an eleventh aspect, in the method for manufacturing a semiconductor chip of the tenth aspect, the Al layer in the electrode is an Al—Si alloy and of thickness of 4 μm or more.

According to a twelfth aspect, in the method for manufacturing a semiconductor chip according to any one of the first to eleventh aspects, the supporting substrate has a shape larger than the semiconductor wafer, and the width (d) of the substrate projecting from the edge of the semiconductor wafer is less than 1 mm.

The supporting substrate appropriately supports the semiconductor wafer in the size larger than the wafer.

The projecting width (d) of the supporting substrate from the edge of the wafer is preferably equal to or less than 1 mm so that no problems are caused during handling between the manufacturing processes.

According to a thirteenth aspect, in the method for manufacturing a semiconductor chip of any one of the first to twelfth aspects, the semiconductor wafer is fixed to the supporting substrate with a thermoplastic resin.

According to a fourteenth aspect, in the method for manufacturing a semiconductor chip according to any one of the first to thirteenth aspects, the thermoplastic resin includes a first resin having a thermal plasticity and a second resin having an acid resistance and an alkaline resistance, and the semiconductor wafer is fixed to the supporting substrate with the first resin placed on an entire surface of the reverse side of the semiconductor wafer and with the second resin covering the edge face of the semiconductor wafer and the edge face of the first resin.

In this manner, the semiconductor wafer is fixed to the supporting substrate by the first resin with thermal plasticity, and the first resin is softened by application of heat in order to remove the semiconductor wafer from the supporting substrate.

Furthermore, by covering the edge face of the semiconductor wafer and the edge face of the first resin with the second resin having acid resistance and alkaline resistance, permeation of chemicals and the like, used for forming the electrode, into the electrode on the reverse side formed in the preceding process will be prevented.

### BRIEF DESCRIPTION OF THE DRAWINGS

The above and other objects, features and advantages of the present invention will become more apparent from the following detailed description made with reference to the accompanying drawings:

FIG. 1A is a schematical cross-sectional view of the semiconductor device according to a preferred embodiment;

FIG. 1B is a schematical cross-sectional view of the semiconductor chip in the semiconductor device shown in FIG. 1A;

FIGS. 2A-2C are schematical cross-sectional views of the semiconductor chip 10 during the manufacturing process; and

FIGS. 3A-3B are schematical cross-sectional views of a conventional semiconductor chip.

### DETAILED DESCRIPTION OF THE PREFERRED EMBODIMENT

A preferred embodiment will be described with reference to the drawings. In each of the drawings, the same or equivalent portions have the same numerals for the purpose of simplicity of description.

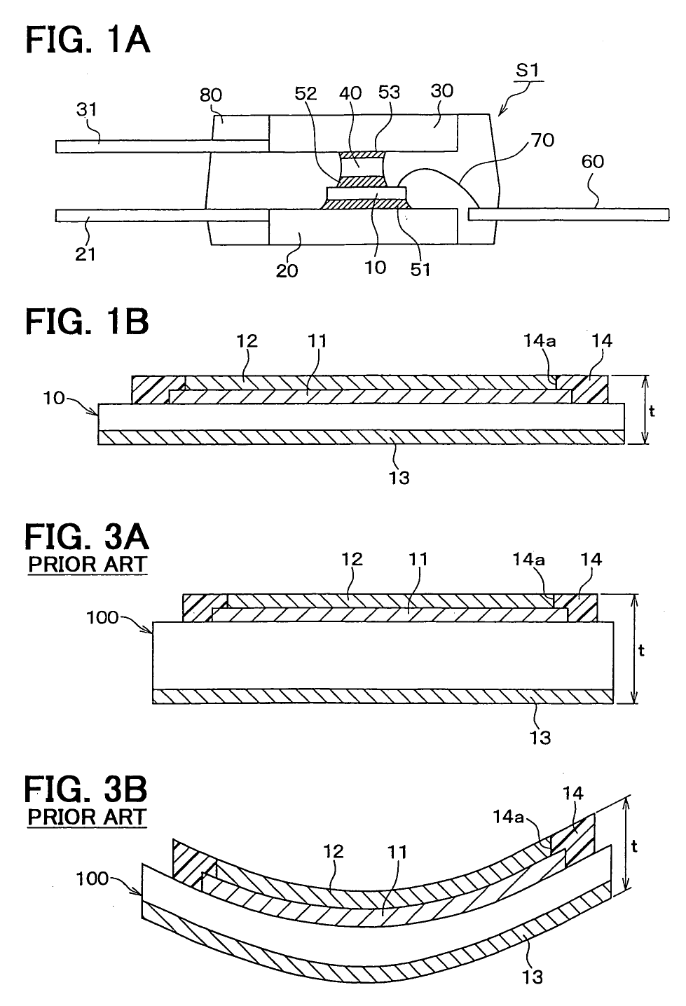

As shown in FIG. 1A, the semiconductor device Si includes a semiconductor chip 10, a lower heatsink 20 as a first metal body, an upper heatsink 30 as a second metal body 30, a heatsink block 40, conductive adhesives 51, 52, 53 interposing between the chip and the heatsinks, and a resin mold 80.

In this structure, a lower side of the semiconductor chip 10 and an upper side of the lower heatsink 20 are connected by the first conductive adhesive 51.

Further, an upper side of the semiconductor chip 10 and a lower side of the heatsink block 40 are connected by the second conductive adhesive 52.

Furthermore, an upper side of the heatsink block 40 and a lower side of the upper heatsink 30 are connected with the third conductive adhesive 53.

A solder, a conductive adhesive agent, or the like may used as the first, second and third conductive adhesives.

In concrete, as the first, second and third conductive adhesive 51, 52, 53, Sn—Ag—Cu type solders for being Pb free, Sn—Ni—Cu type solders and the like for being Sn (tin) type, are used.

According to the structure described above, the heat dissipation is conducted through the second conductive adhesive 52, the heatsink block 40, the third conductive adhesive 53 and the upper heatsink 30 on the upper side of the semiconductor chip 10, and through the first conductive adhesive and the lower heatsink 20 on the lower side of the chip 10.

The semiconductor chip 10 may include, for example, an IGBT (Insulated Gate Bipolar Transistor) and a power element such as a thyristor.

In concrete, the semiconductor chip 10 is, for example, in the shape of a rectangular thin board. The thickness t of the chip is, for example, 250 μm or less.

As shown in FIG. 1B, the upper side of the semiconductor chip 10, which will be referred to as the main side, serves as an active element region side where an active element such as a transistor and the like are formed, and the lower side will be referred to as the reverse side. In this case, an active element such as a transistor is formed by making an impurity diffused layer with thermal diffusion, ion implantation or the like.

The semiconductor chip 10 has an electrode 12, 13 on each of the upper side and the lower side, as shown in FIG. 1B.

More particularly, the main side includes an electrode 12 that will be referred to as the main side electrode 12, and the reverse side includes an electrode 13 that will be referred to as the reverse side electrode 13. The main side electrode 12 is, for example, an emitter electrode or a gate electrode of a transistor, and the reverse side electrode 13 is, for example, a collector electrode of a transistor.

The main side of the semiconductor chip 10 has an Al—Si layer 11 made of Al—Si, as shown in FIG. 1B. This Al—Si layer 11 is a film formed by a Physical Vapor Deposition method (PVD) such as deposition, sputtering and the like, and has a film thickness of, for example, approximately 4 μm or more.

A protection film 14 is formed on this Al—Si layer 11, using an electrical insulating material. This protection film 14 is, for example, formed by a spin coat method with an electrical insulating material such as a polyimide and the like.

In this protection film 14, an opening 14a is formed to expose the surface of the Al—Si layer 11. The opening 14a is formed by, for example, photo-lithography etching. On the surface of the Al—Si layer 11 in the opening 14a, the main side electrode 12 made of a plating layer is formed.

In the present embodiment, the main side electrode 12 is formed from a layered film comprised of the Ni—P plating layer and Au plating layer formed on the surface of the Al—Si layer 11 by wet electroless deposition, that is, an electroless Ni/Au plating film.

In this case, the P density in the Ni—P layer is preferably 5 to 15% by weight, the thickness of the Ni—P layer is preferably 3 μm or more, and the thickness of the Au layer is preferably 0.02 to 0.2 μm. For example, the thickness of the Ni—P plating layer may be approximately 4 μm, and the thickness of the Au plating layer may be approximately 0.1 μm.

In the present embodiment, the main side of the semiconductor chip 10 is the element active region side, and the main side electrode 12 on the main side is made of the Ni—P layer and Au layer stacked in this order.

In the present embodiment, as shown in FIG. 1B, the reverse side electrode 13 formed on the reverse side of the semiconductor-chip 10 is formed by a physical vapor deposition method (PVD) such as vacuum deposition, sputtering or the like on the whole surface of the reverse side.

In this case, the reverse side electrode 13 is a film made from four layers of Al/Ti/Ni/Au. This is formed by layering the Al layer, Ti layer, Ni layer and Au layer in this order on the reverse side by sputtering or the like. For example, the Ti layer may be approximately 200 nm, the Ni layer may be approximately 600 nm, and the Au layer may be approximately 100 nm.

As described above, in the present embodiment, the reverse side electrode 13 on the reverse side of the semiconductor chip 10 is connected electrically to the first metal body serving as the lower heatsink 20 through the first conductive adhesive 51, and the main side electrode 12 on the main side of the semiconductor chip 10 is connected electrically to the heatsink block 40 through the second conductive adhesive 52.

Further, on the side opposite to side of the heatsink block 40 facing the semiconductor chip 10, the heatsink block 40 and the second metal body serving as the upper heatsink 30 are connected electrically through the third conductive adhesive 53.

In this case, the lower heatsink 20, the upper heatsink 30 and the heatsink block 40 are, for example, made of metal having high thermal/electrical conductivity such as copper alloy, aluminum alloy or the like. The heatsink block 40 may be made of a typical iron alloy.

The lower heatsink 20 may take the shape of a rectangular board as a whole. A terminal portion 21 is disposed to protrude from the lower heatsink 20. The terminal portion 21 serves as an external connection electrode for the reverse side electrode 13, that is, for example, a collector electrode, on the reverse side of the semiconductor chip 10.

The heatsink block 40 is shaped as a rectangular board one size smaller than the semiconductor chip 10.

The heatsink block 40 is interposed between the semiconductor chip 10 and the upper heatsink 30, to thereby thermally and electrically connect the chip 10 and the upper heatsink 30. The heatsink block 40 also serves as a spacer to secure a height sufficient for permitting a later-mentioned bonding wire to be attached to the chip 10.

The upper heatsink 30 is also made in a shape of a rectangular board as a whole. The upper heatsink 30 also has a protruding terminal portion 31, used as an external connection electrode for the main side electrode 12, that is, for example an emitter electrode, on the main side of the semiconductor chip 10.

The terminal portion 21 of the lower heatsink 20 and the terminal portion 31 of the upper heatsink 30 are, as described above, the external connection electrodes for the electrodes 12, 13 on the semiconductor chip 10. That is, these terminal portions 21, 31 are disposed on the semiconductor device S1 for connection to external wiring members and the like.

In this manner, the lower heatsink 20 and the upper heatsink 30 are disposed as the first and second metal bodies that function as electrodes as well as radiators.

A signal terminal 60 made from lead frame is disposed on the perimeter of the semiconductor chip 10. The signal terminal 60 is used as an electrode for connecting to the main side electrode 12, that is, for example a gate electrode, or a reference electrode.

For example, the signal terminal 60, as shown in FIG. 1A, is connected electrically to the main side of the semiconductor chip 10 by a wire 70. The wire 70 is formed during a process such as a wire bonding or the like, and is made of a material such as gold, aluminum, or the like.

Further, the semiconductor device SI of the present embodiment is almost entirely sealed by resin mold 80. In concrete, a space between the heatsinks 20, 30, and a space around the semiconductor chip 10 and the heatsink block 40 are filled and sealed with the resin mold 80.

The resin mold 80 is, for example, made of typical mold materials such as an epoxy resin or the like. Molding of the heatsinks 20, 30 and the like with the resin mold 80 is easily conducted by a transfer mold method with an upper and lower mold (not shown in FIGS.)

In this manner, the semiconductor device S1 in the present embodiment is basically composed of a resin mold type semiconductor device having the semiconductor chip 10 as a vertical power element with metal bodies 20, 30, 40 electrically and thermally connected to the main side and the reverse side of the chip 10 by using the conductive adhesives 51, 52, 53.

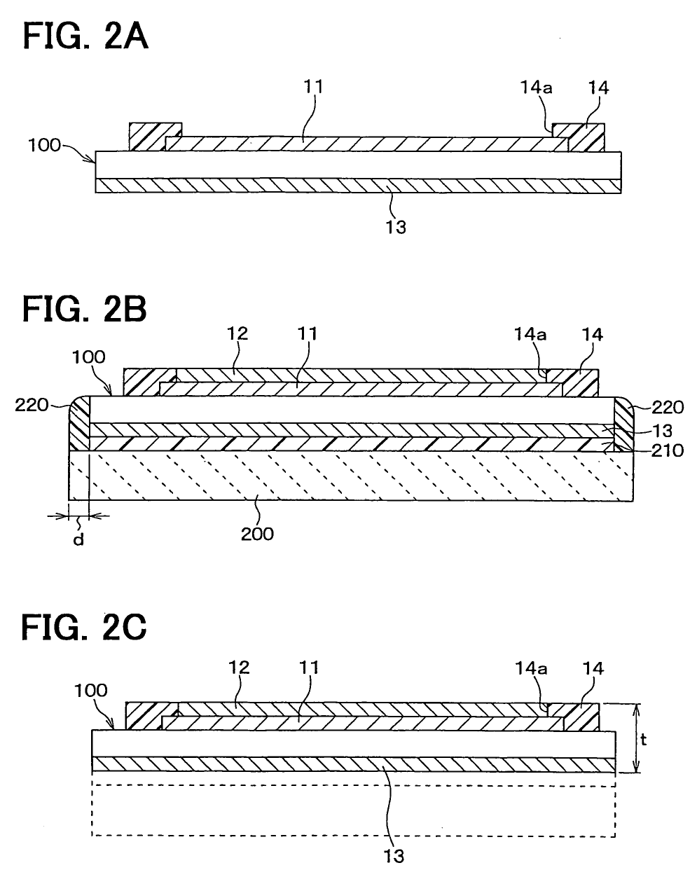

Next, a method for manufacturing the semiconductor device S1 described above is explained with reference FIGS. 1A-1B and FIGS. 2A-2C.

As shown in FIG. 2A, the semiconductor wafer 100 processed to be the semiconductor chip 10 is prepared, having an upper side as a main side and a lower side as a reverse side. The main side and the reverse side of the semiconductor wafer 100 are the same as those of the semiconductor chip 10.

The semiconductor wafer 100 is a thin board, having a thickness of 250 μm or less. The main side of the semiconductor wafer 100 has, though not shown in the FIGS., semiconductor elements such as a transistor and the like in a unit pattern of a semiconductor chip formed by an element formation process such as ion implantation, diffusion or the like.

On the main side of the semiconductor wafer, the Al—Si layer 11 is formed by sputtering, photolithography or the like (Al—Si layer formation process). Then, a protection film formation process is conducted to form the protection film 14 on the Al—Si layer 11 by the spin coat method or the like, succeeded by a photo etching process or the like to form an opening 14a in the protection film 14.

Then, the reverse side electrode 13 is formed on the reverse side of the semiconductor wafer 100 (reverse side electrode formation process). In concrete, the Al layer, the Ti layer, the Ni layer, and the Au layer are formed in this order on the reverse side of the semiconductor wafer 100 by sputtering. As a result, an Al/Ti/Ni/Au film is formed as the reverse side electrode 13.

Then, the main side electrode 12 is formed on the main side of the semiconductor wafer 100 while the reverse side of the semiconductor wafer 100 is fixed to the supporting substrate 200, as shown in FIG. 2B (main side electrode formation process).

Preferably, the supporting substrate 200 has greater rigidity than the semiconductor wafer 100. The substrate 200 is, for example, mainly made of quartz. More concretely, a board of Pylex (registered trademark) glass or the like is used as the supporting substrate 200. The supporting substrate 200 preferably has a thickness of 0.4 mm or more.

The size of the supporting substrate 200 is preferably larger than the semiconductor wafer 100, and the projecting width of the supporting substrate 200 from the edge of the semiconductor wafer 100 is preferably less than 1 mm.

The method of fixing the semiconductor wafer 100 to the supporting substrate 200 is, not limited to a specific type, as long as the method enables removal of the semiconductor wafer 100 appropriately from the supporting substrate 200 in the later process. In the present embodiment, fixation is conducted by using thermal plastic resin 210, 220.

More particularly, as shown in FIG. 2B, the thermal plastic resins are the first resin 210 with thermal plasticity, and the second resin 220 with acid resistance and alkaline resistance in the present embodiment.

The fixation of the semiconductor wafer 100 to the supporting substrate 200 is performed by applying and drying the first resin 210 on the entire surface of the reverse side of the semiconductor wafer 100, and applying and drying the second resin 220 on the edge face of the semiconductor wafer 100 and the edge face of the first resin 210.

For example, the first resin 210 is made of thermal plastic resin or the like, and the second resin 220 is made of asphalt, natural oils and fats or the like.

The second resin 220 is preferably insoluble in a liquid of pH 1 to 14, and soluble in an organic solvent such as xylene. This is because an alkaline is used in the neutralization step of plating during the deposition process of the main side electrode 12 formation described later.

Next, the main side electrode formation process is conducted on the semiconductor wafer 100 fixed to the supporting substrate 200.

Particularly, on the surface of Al—Si layer exposed in the opening 14a, the main side electrode 12 is formed by electroless plating. The main side electrode 12 including the Ni—P layer and the Au plating layer is formed on the main side of the semiconductor wafer 100 in this manner.

Next, the semiconductor wafer 100 with the electrode 12, 13 formed on both of the main side and the reverse side is removed from the supporting substrate 200 (supporting substrate removal process), as shown in FIG. 2C.

In concrete, the second resin 220 is dissolved and removed by using the organic solvent, and the first resin 210 is melted by laser irradiation or exposing the semiconductor wafer 100 in an atmosphere of high temperature. The thickness t of the fabricated semiconductor wafer is 250 μm or less.

Then, the semiconductor wafer 100 is divided into a separate chip by dicing to make the semiconductor chip 10.

The semiconductor chip 10 is implemented in the following manner. The semiconductor chip 10 and the heatsink block 40 are first soldered on the lower heatsink 20 in the first place.

In concrete, solder foil made of Sn type solder, for example, is applied to the upper side of the lower heatsink 20 to place the semiconductor chip 10 thereon, and the same solder foil is applied on the semiconductor chip 10 to place the heatsink block 40 thereon.

The solder foil is melted in a heater (a reflow apparatus) by raising the temperature above the melting point of the solder and then hardened.

Next, a wire bonding process of the semiconductor chip 10 and the signal terminal 60 is conducted. In this process, the semiconductor chip 10 and the signal terminal 60 are connected electrically by the wire 70.

Next, a soldering process of the upper heatsink 30 to each heatsink block 40 is conducted. The upper heatsink 30 is placed on the heatsink block 40 with the interposing solder foil. The solder foil is heated by a heater and then hardened.

In this manner, the hardened solder foils form the first, second and third conductive adhesives 51, 52, 53.

The conductive adhesives 51, 52, 53 electrically and thermally connect the lower heatsink 20, the semiconductor chip 10, the heatsink block 40 and the upper heatsink 30.

When the conductive adhesive agents are used as the first, second and third conductive adhesives 51, 52, 53, the electrical and thermal conductivity between the lower heatsink 20, the semiconductor chip 10, the heatsink block 40 and the upper heatsink 30 is achieved by replacing the solders with the conductive adhesive agents and applying/hardening the conductive adhesive agents.

Then, a resin mold process, filling the resin mold 80 into the spaces between and around the heatsinks 20, 30, is conducted by using a form block (not shown in FIGS.). In this process, as shown in FIG. 1A, the spaces between and around the heatsinks 20, 30 are filled and sealed by the resin mold 80. In this manner, the semiconductor device S1 is fabricated.

In the semiconductor device S1, the lower side of the lower heatsink 20 and the upper side of the upper heatsink 30 are exposed from the resin mold 80 according to the structure described above. This structure facilitates the heat dissipation efficiency of the heatsinks 20, 30.

In the present embodiment, the manufacturing method of the semiconductor chip 10 with the electrodes 12, 13 formed on each of the main side and the reverse side, having the metal bodies 20, 30 as electrodes and radiators attached on each of the main side and the reverse side, and a resin mold 80 covering almost an entire body of the semiconductor device S1, is characterized by the following points.

That is, the semiconductor wafer 100, to be divided into the semiconductor chip 10 with the same orientation in terms of the main side and the reverse side as the chip 10, is prepared to have the reverse side electrode 13 formed on the reverse side of the semiconductor wafer 100, and then to have the main side electrode 12 formed on the main side while the wafer 100 is fixed to the supporting substrate 200, and finally to have the chip 10 cut out from the wafer 100 by, for example, dicing, after the wafer 100 has been removed from the supporting substrate 200.

According to the method, the semiconductor wafer 100 is fixed to the supporting substrate 200 before forming the electrodes 12, 13 on both sides of the semiconductor wafer 100, so that the warpage of the semiconductor wafer 100 is minimized.

In the present embodiment, the supporting substrate 200 preferably has a greater rigidity than the semiconductor wafer 100, e.g. a material mainly made of quartz, and the thickness of the substrate 200 is preferably 0.4 mm or more.

The supporting substrate 200, being made of the material and the thickness, appropriately supports the semiconductor wafer 100.

In the present embodiment, the size of the supporting substrate 200 is preferably larger than the semiconductor wafer 100, and the projecting width d (shown in FIG. 2B) of the supporting substrate 200 from the edge of the semiconductor wafer 100 is equal or less than 1 mm.

The supporting substrate 200, being the size larger than the semiconductor wafer 100, appropriately supports the semiconductor wafer 100.

The projecting width d of the supporting substrate 200 from the edge of the wafer 100 is preferably equal to or less than 1 mm to not cause a problem in handling the work between the manufacturing processes.

In the present embodiment, the semiconductor wafer 100 is fixed to the supporting substrate 200 with two kinds of thermoplastic resins, that is, the first resin 210 with thermal plasticity and the second resin 220 with acid/alkaline resistance. The first resin 210 is applied on the entire surface of the reverse side of the semiconductor wafer 100, and the second resin 220 is applied on the edge face of the semiconductor wafer 100 and the edge face of the first resin 210.

The first resin 210 with thermal plasticity fixes the semiconductor wafer 100 to the supporting substrate 200. The first resin 210 is melted in a heater when the semiconductor wafer 100 is removed from the supporting substrate 200.

By covering the edge face of the semiconductor wafer 100 and the edge face of the first resin 210 with the second resin 220 having acid/alkaline resistance, permeation of chemicals and the like, used for forming the electrode 12, into the electrode 13 on the reverse side formed in the preceding process will be prevented.

In the present embodiment, the P density in the Ni—P layer is preferably 5 to 15% by weight, and the thickness of the layer is preferably 3 μm or more in the main side electrode 12 on the semiconductor chip 10, as described above.

When the P density in the Ni—P layer is too thick, the Ni—P plating layer and the Sn in the solder tend to react in the soldering process of the main side electrode 12 on the semiconductor chip 10.

The chemical reaction tends to form a P thickened layer in the proximity of the interface of the underlying Al layer 11. The P thickened layer causes easy exfoliation of the Ni—P plating layer and the Al—Si layer 11.

The P in the Ni—P plating layer becomes a nucleus to work as an accelerator for forming a film in the wet electroless deposition process. In other words, Ni as a simple substance does not contribute to the growth of a plating layer to form a film.

Therefore, when the P density in the Ni—P layer is too thin, the Ni—P plating layer is not easily formed. The P with the density too thin makes the film harder (Ni rich film). The hard film is not preferred because of the tendency to warp.

A P thickened layer is also, not preferably, formed in the proximity of the interface of the underlying Al layer 11 when the thickness of the Ni—P layer is too thin.

According to the facts described above, the P density in the Ni—P layer is preferably 5 to 15% by weight, and the thickness of the layer is preferably 3 μm or more in the main side electrode 12 formed on the semiconductor chip 10.

In the present embodiment, the Au layer in the electrode 12 formed on the semiconductor chip 10 preferably has a thickness of 0.02 to 0.2 μm, as described above.

The Au layer in the main side electrode 12 is formed to prevent oxidization of the underlying layer. When the thickness of the Au layer is thinner than 0.02 μm, it will not fully be functional as an anti-oxidization film.

On the contrary, an Al—Au—Ni alloy tends to be formed in the wire bonding process of the main side electrode 12 formed on the semiconductor chip 10 when the Au layer is thicker than 0.2 μm. This alloy is easy to corrode, and thus the thickness of the Au layer should be 0.2 μm or less.

According to the facts described above, the Au plating layer in the main side electrode 12 on the main side of the semiconductor chip 10 preferably has the thickness of 0.02 to 0.2 μm in the present embodiment.

The semiconductor chip 10, in the above described manufacturing method for the present embodiment, has, as the main side electrode 12, the Ni—P plating layer with P density of 5 to 15% by weight and a thickness of 3 μm or more, and an Au layer with thickness of 0.02 to 0.2 μm. The Ni—P layer and the Au layer are formed by wet electroless deposition.

According to the conditions described above, the present embodiment will benefit from the combination of effects described in the preferable embodiments regarding the Ni—P layer and the Au layer respectively.

In the present embodiment, the thickness of the Al—Si layer 11, or Al—Si alloy, is 4 μm or more as the main side electrode 12 on the semiconductor chip 10.

### Other Embodiment

The main side electrode 12 and the reverse side electrode 13 on the semiconductor chip 10 are not limited to the configurations described in the above embodiment. The electrodes need only be able to be soldered or connected by the conductive adhesive or the like to the upper and lower heatsinks 20, 30 and the heatsink block 40.

In the above embodiment, the semiconductor wafer 100 is cut into the chip after the wafer 100 is removed from the supporting substrate 200 in the manufacturing process. The wafer 100 may be cut with the supporting substrate 200 while the wafer 100 is fixed to the supporting substrate 200. The pieces of the supporting substrate 200 may be removed from the semiconductor chip 10 afterwards.

The heatsink block 40, as described above, interposes between the semiconductor chip 10 and the upper heatsink 30, serves as a spacer to secure the height between the chip 10 and the heatsink 30. However, the heatsink block 40 may be omitted in the above-mentioned embodiment, when possible.

In brief, according to the semiconductor chip manufacturing process of the present disclosure, the main side electrode 12 on the semiconductor wafer 100 is formed while the wafer 100 is fixed to the supporting substrate 200 after forming the reverse side electrode 13. The final semiconductor device S1 includes the semiconductor chip 10 with the electrodes 12, 13 on the main side and the reverse side respectively, having the metal bodies 20, 30 as electrodes and radiators attached on each of the main side and the reverse side, and a resin mold 80 covering almost an entire body of the device. The design of the other portion may suitably be changed.

The description of the invention is merely exemplary in nature and, thus, variations that do not depart from the gist of the invention are intended to be within the scope of the invention. Such variations are not to be regarded as a departure from the spirit and scope of the invention.

1. A method for manufacturing a semiconductor chip having electrodes respectively formed on a main side and a reverse side of the semiconductor chip, metal bodies attached to the main side and the reverse side, and a resin mold encapsulating the semiconductor chip, the manufacturing method comprising:
preparing a semiconductor wafer to be oriented similar to the semiconductor chip with respect to a main side and reverse side of the semiconductor wafer;
forming an electrode on the reverse side of the semiconductor wafer;
forming an electrode on the main side of the semiconductor wafer while the reverse side of the wafer is fixed to a supporting substrate; and
cutting the semiconductor wafer to form the semiconductor chip.

2. The method of claim 1, wherein the supporting substrate has a greater rigidity than that of the semiconductor wafer.

3. The method of claim 1, wherein the supporting substrate is comprised of quartz.

4. The method of claim 1, wherein a thickness of the supporting substrate is 0.4 mm or more.

5. The method of claim 1, wherein a thickness of the semiconductor wafer is less than 250 μm.

6. The method of claim 1, wherein the main side of the semiconductor chip includes an active region, wherein the electrode on the main side is comprised of an Ni—P layer and an Au layer stacked on an aluminum layer.

7. The method of claim 6, wherein the Ni—P layer and the Au layer are formed by wet electroless deposition.

8. The method of claim 6, wherein the Ni—P layer of the electrode on the main side has a P density of 5 to 15% by weight and a thickness of 3 μm or more.

9. The method of claim 6, wherein the Au layer in the electrode on the main side has a thickness of 0.02 to 0.2 μm.

10. The method of claim 6, wherein the Ni—P layer in the electrode on the main side has a P density of 5 to 15% in weight and a thickness of more than 3 μm, wherein the Au layer in the electrode on the main side has a thickness of 0.02 to 0.2 μm, wherein the Ni—P layer and the Au layer are formed by a wet electroless deposition.

11. The method of claim 10, wherein the Al layer in the electrode on the main side is comprised of an Al—Si alloy, wherein the Al layer has a thickness of 4 μm or more.

12. The method of claim 1, wherein the supporting substrate has a shape larger than the semiconductor wafer, and wherein a projecting width of the substrate from the edge of the semiconductor wafer is less than 1 mm.

13. The method of claim 1, wherein the semiconductor wafer is fixed to the supporting substrate with a thermoplastic resin.

14. The method of claim 13, wherein the thermoplastic resin comprises a first resin having a predetermined thermal plasticity and a second resin having a predetermined acid resistance and alkaline resistance, wherein the semiconductor wafer is fixed to the supporting substrate by placing the first resin on an entire surface of the reverse side of the semiconductor wafer and covering the edge face of the semiconductor wafer and the edge face of the first resin with the second resin.

15. The method of claim 1, further comprising removing the supporting substrate after forming the electrode on the reverse side of the semiconductor wafer and the electrode on the main side of the semiconductor wafer.

16. A method for manufacturing a semiconductor chip comprising:
preparing a semiconductor wafer to be oriented to have a main side and reverse side of the semiconductor wafer oriented similar to a main side and reverse side of the semiconductor chip intended to be cut from the semiconductor wafer;
forming an electrode on a reverse side of the semiconductor wafer;
forming an electrode on the main side of the semiconductor wafer while the reverse side of the wafer is fixed to a supporting substrate, and
cutting the semiconductor wafer to form the semiconductor chip.
